(19) United States
(12) Patent Application Publication
(10) Pub. No.: US 2006/0120196 A1
(43) Pub. Date: Jun. 8, 2006

(54) Trimming circuits including isolated well regions and related memory devices

(76) Inventors: Hong-Soo Jeon, Gyeonggi-do (KR); Seung-Keun Lee, Gyeonggi-do (KR)

Correspondence Address: MYERS BIGEL SIBLEY & SAJOVEC, PO BOX 37428, RALEIGH, NC, 27627, US

(21) Appl. No.: 11/240,236

(22) Filed: Sep. 30, 2005

(30) Foreign Application Priority Data
Nov. 4, 2004 (KR) 2004-89436

(51) Int. Cl. G11C 5/14

(52) U.S. Cl. 365/226

(57) ABSTRACT

A trimming circuit may include a plurality of resistors coupled in series between an output node and a reference voltage, and a plurality of transistors. More particularly, each transistor of the plurality of transistors may be electrically coupled in parallel with a respective one of the resistors. Moreover, each of the transistors may include a respective well region, and well regions of different transistors may be isolated. Related memory devices are also discussed.

### RELATED APPLICATIONS

This U.S. non-provisional patent application claims the benefit of priority under 35 U.S.C. § 119 from Korean Patent Application 2004-89436 filed on Nov. 4, 2004, the disclosure of which is hereby incorporated herein in its entirety by reference.

### FIELD OF THE INVENTION

The present invention relates to semiconductor memory devices, and more particularly to trimming circuits for semiconductor memory devices and related methods.

### BACKGROUND

Semiconductor memories are widely used in applications from customer electronic industries to satellite technologies. Therefore, technical advancement in manufacturing semiconductor memories with increased density and speed may advance standards of performance for digital electronic devices including semiconductor memory devices.

In general, semiconductor memories are roughly classified into volatile semiconductor memory devices and nonvolatile semiconductor memory devices. Volatile semiconductor memory devices are able to store and read data only as long as a power supply is uninterrupted, but may lose data when a power supply is interrupted. Nonvolatile semiconductor memory devices, such as mask ROM (Read Only Memory), a programmable ROM (PROM), an erasable and programmable ROM (EPROM), or an electrically erasable and programmable ROM (EEPROM), may retain data even if a power supply is interrupted.

Storage endurance in a nonvolatile memory device can be designed to be reprogrammable or permanent in accordance with manufacturing techniques. With nonvolatile memory devices such as mask ROMs, PROMs, and EPROMs, updating data stored therein by users may be inconvenient because erasing and writing data may be difficult once integrated in a system. EEPROMs may be used in applications with system programming devices requiring continuous data update or for subsidiary storage units because EEPROMs allow electrically erasing and writing data stored therein. In particular, flash EEPROMs (hereinafter, referred to as “flash memory”) may be used for large-capacity subsidiary storage units because of the relatively high integration density. Flash memories may be classified as NOR type and NAND type according to connection patterns between bitlines and memory cells. A NOR type flash memory may be effective for relatively high speed operations, but NOR type flash memories may have relative large current consumption potentially limiting increases in integration densities. A NAND type flash memory may allow higher integration densities because a NAND type flash memory may consume less current than a NOR type flash memory.

FIG. 1 is a block diagram illustrating a configuration of a NOR type flash memory device including a general wordline voltage generator. As shown in FIG. 1, the NOR type flash memory device includes a memory cell array 10 having a plurality of memory cells arranged at intersections of rows (defined by wordlines WL0˜WLi) and columns (defined by bitlines BL0˜BLj). A voltage VPW supplied from a wordline voltage generator 30 may be used as a wordline voltage (or read voltage) applied to a wordline WLi through a decoder 20. The wordline voltage generator 30 may include a high voltage generator 40 and a voltage regulator 50. The high voltage generator 40 may generate a relatively high voltage VPP greater than a power source voltage in response to a boost enable signal EN provided from a program controller (not shown). The voltage regulator 50 may adjust a level of the high voltage VPP in response to control of the program controller. As shown in FIG. 2, the voltage regulator 50 may include a trimming circuit 54 to precisely adjust a voltage at a relatively fine level. A structure of a trimming circuit 54, as a kind of voltage divider, is disclosed in U.S. Pat. No. 5,642,309 entitled “AUTO-PROGRAM CIRCUIT IN A NONVOLATILE SEMICONDUCTOR MEMORY DEVICE”, the disclosure of which is hereby incorporated herein in its entirety by reference. When the voltage regulator 50 includes the trimming circuit 54 therein, the program controller may apply a trimming control signal TRIMi to the voltage regulator 50 to regulate an operation of the trimming circuit 54.

FIG. 2 is a circuit diagram illustrating a structure of the regulator 50 including the trimming circuit 54. As shown in FIG. 2, the voltage regulator 50 includes a drive circuit 52 and a comparator 56, together with the trimming circuit 54. A resistor R may be connected between the trimming circuit 54 and a ground voltage, acting as a divider.

The trimming circuit 54 distributes the voltage VPW, which is generated by the drive circuit 52, in a predetermined resistance ratio in response to the trimming control signal TRIMi provided from the program controller. The comparator 56 determines whether a resulting voltage Vdiv (divided by the trimming circuit 54) is higher than a reference voltage Vref. The drive circuit 52 adjusts the magnitude of current generated in accordance with the output of the comparator 56. If the divided voltage Vdiv is lower than the reference voltage Vref (Vdiv<Vref), the drive circuit 52 supplies a current to the trimming circuit 54, which makes the voltage VPW rise up to a required level. If the divided voltage Vdiv is higher than the reference voltage Vref (Vdiv>Vref), the drive circuit 52 interrupts a current flowing toward the trimming circuit 54, which makes the voltage VPW fall to a required level. While the trimming circuit 54 is illustrated within the voltage regulator 50, the trimming circuit 54 may be provided outside of the regulator 50 as an independent component.

FIGS. 3 and 4 are circuit diagrams illustrating trimming circuits 54 of FIG. 2, and FIG. 5 illustrates a vertical cross section of the trimming circuit shown in FIG. 3.

FIG. 3 shows a trimming circuit 540 without level shifters, and FIG. 4 shows a trimming circuit 640 with level shifters. The trimming circuit 640 of FIG. 4 is substantially similar to the trimming circuit 540 of FIG. 3, except that the level shifters 641˜645 transform voltage levels into voltages to be trimmed. Thus, the trimming circuit 540 will be described as representative. The voltage VN1 is a voltage at a first node N1 shown in FIG. 2, and the voltage VN2 is a voltage at a second node N2 shown in FIG. 2.

As illustrated in FIG. 3, the trimming circuit 540 includes a plurality of PMOS transistors 541˜545 connected in series between the first and second nodes, N1 and N2. Resistors R1˜R5 are respectively connected between sources and drains of the PMOS transistors 541˜545 for voltage division. The sources of the transistors 541˜545 are connected to a higher voltage derived from VN1 supplied from the first node N1. Bulks of the PMOS transistors 541˜545 are connected in common with sharing an N-well region as shown in FIG. 5. A high voltage of VPW is applied to the common bulk through an additional voltage terminal. The high voltage VPW has the same level as the high voltage VN1 of the first node N1. The trimming circuit 540 of FIG. 3 may include NMOS transistors instead of PMOS transistors, or both NMOS and PMOS transistors.

The PMOS transistors 541˜545 carry out switching operations in response to the trimming signals TRIMi (i is 1˜5). The switching operations by the PMOS transistors 541˜545 change a current path between the first and second nodes N1 and N2. For example, if the first PMOS transistor 541 is turned off by the first trimming control signal TRIM1 at a high level, the current may flow primarily through the first resistor R1 (see the arrow 1) instead of PMOS transistor 541. And, if the second PMOS transistor 542 is turned on by the second trimming control signal TRIM2 at a low level, the current may flow primarily through the second PMOS transistor 542 instead of the second resistor R2 (see the arrow 2). As a result, the divided voltage Vdiv from the trimming circuit 540, i.e., the voltage NV2 of the second node N2, may be changed.

As is well known, the PMOS transistors 541˜545 may be connected in series as shown in FIG. 3 and may be formed in a single well of the common bulk of a semiconductor substrate as shown in FIG. 5 for high integration density. And, the high voltage VPW is applied to the common bulk of the PMOS transistors 541˜545, in addition to voltages applied between the first and second nodes N1 and N2, which is a program voltage generated from the regulator 50 and substantially identical to the voltage VN1 of the first node N1. The reason for applying the high voltage VPW to the bulk is to reduce body effect due to a voltage difference between the source and the bulk. With such an architecture, however, the trimming circuit 540 may not be free from body effect for reasons discussed below.

A source voltage of each transistor may increase in accordance with the supply of the high voltages, VN1 and VPW, to the sources and bulk of the PMOS transistors 541˜545 (i.e., MOS transistors). Although the source and bulk may be supplied with the same voltage, there may be a voltage difference between the source and the bulk because of parasitic inductance inherent in the source. As a result, the source-to-bulk voltage Vsh may increase to cause extension of a depletion layer. A voltage difference between a gate and a channel of the transistor may become larger so that a threshold voltage of the transistor may vary. The variation of the transistor may act as a factor degrading accuracy of voltage division by the trimming circuit 540. Such a body effect due to the voltage difference between the source and the bulk in the MOS transistor may be more serious in a high voltage condition than in a low voltage condition.

FIG. 6 is a graphic diagram showing a waveform of a signal output from the regulator 50 including the trimming circuit 540 shown in FIG. 5. As illustrated in FIG. 6, a required program voltage Target TPW is represented by a solid line, while the program voltage TPW generated from the regulator 50 may be represented by a broken line. It can be seen from FIG. 6 that the operational accuracy of the voltage regulator 50 may be degraded with the reduced performance of the voltage division in the trimming circuit 540 due to the body effect. A difference between the required program voltage Target VPW and the practical program voltage VPW, ΔVW, may be 0.05˜0.06V.

In particular, considering that a program voltage of a multilevel cell flash memory storing a plurality of data bits in a single cell steps up by 0.1˜0.2V, such a voltage difference ΔVW may affect the reliability of the voltage trimming function.

### SUMMARY

According to some embodiments of the present invention, a trimming circuit may include a plurality of resistors coupled in series between an output node arid a reference voltage, and a plurality of transistors. Each of the transistors may be electrically coupled in parallel with a respective one of the resistors. Moreover, each of the transistors may include a respective well region, and well regions of different transistors may be isolated.

The well regions of the different transistors may include separate doped regions of a same substrate, and the plurality of transistors may inlcude a plurality of field effect transistors. More particularly, a well region of a first one of the plurality of transistors may be coupled to a source/drain of a second one of the plurality of transistors.

Each of the transistors may include source and drain regions in the respective well region. For example, one of the transistors may be a P-type field effect transistor, and the source region of the P-type transistor may be electrically coupled to the well region of the P-type transistor. More particularly, the source and well regions of the P-type transistor may be electrically coupled via a metal line providing a direct electrical coupling therebetween. In an alternative, one of the transistors may be an N-type field effect transistor, and the drain region of the N-type transistor may be electrically coupled to the well region of the N-type transistor. More particularly, the drain and well regions of the N-type transistor may be electrically coupled via a metal line providing a direct electrical coupling therebetween.

In addition, a memory cell array may include a plurality of memory cells, and a decoder may be configured to couple the output node with at least one of the memory cells responsive to a memory cell address. More particularly, the memory cells may be flash memory cells.

According to some additional embodiments of the present invention, an integrated circuit memory device may include a memory cell array having a plurality of memory cells, a voltage generator, and a trimming circuit. The voltage generator may be configured to generate a programming voltage for the memory cell array, and the trimming circuit may be coupled to an output of the voltage generator. In addition, the trimming circuit may include a plurality of resistors coupled in series between an output node of the voltage generator and a reference voltage and a plurality of transistors. Each of the transistors may be electrically coupled in parallel with a respective one of the resistors, each of the transistors may include a respective well region, and well regions of different transistors may be isolated.

The well regions of the different transistors may include separate doped regions of a same substrate, and the plurality of transistors may include a plurality of field effect transistors. A well region of a first one of the plurality of transistors may be coupled to a source/drain of a second one of the plurality of transistors.

Each of the transistors may include source and drain regions in the respective well region. For example, one of the transistors may be a P-type field effect transistor, and the source region of the P-type transistor may be electrically coupled to the well region of the P-type transistor. More particularly, the source and well regions of the P-type transistor may be electrically coupled via a metal line providing a direct electrical coupling therebetween. In an alternative, one of the transistors may be an N-type field effect transistor, and the drain region of the N-type transistor may be electrically coupled to the well region of the N-type transistor. More particularly, the drain and well regions of the N-type transistor may be electrically coupled via a metal line providing a direct electrical coupling therebetween.

In addition, the integrated circuit memory device may include a decoder configured to couple the output node of the voltage generator with at least one of the memory cells responsive to a memory cell address. Moreover, the memory cells may include flash memory cells

According to embodiments of the present invention, a trimming circuit of a semiconductor memory device, may provide more precise voltage control operation.

According to some embodiments of the present invention, a trimming circuit may include a plurality of resistors dividing a voltage, and a plurality of switches each connected to the resistors. The switches may be formed respectively in well regions isolated from each other.

According to some additional embodiments of the present invention, a semiconductor memory device may include a memory cell array having a plurality of memory cells. A voltage generator may provide a voltage to be used in programming the memory cells. A trimming circuit may control a level of the voltage. The trimming circuit may include a plurality of resistors dividing a voltage, and a plurality of switches each connected to the resistors. The switches may be formed respectively in well regions isolated from each other.

According to some other embodiments of the present invention, the switches may be formed in a same substrate. One of the well regions may be connected to an adjacent one of the well regions. One of the switches may be biased by a voltage provided from an adjacent one of the switches by way of the connected well regions. More particularly, the switches may be transistors. A source, a drain, and a bulk may be formed in a well region of each of the transistors. Moreover, when the transistor is a P-type transistor, the source and the bulk may be connected within the well region. Otherwise, when the transistor is an N-type transistor, the drain and the bulk may be connected within the well region.

In addition, one of the well regions of the transistors may be connected to an adjacent one of the well regions of the transistors. One of the transistors may be biased by a voltage provided from an adjacent one of the transistors by way of the connected well regions.

### BRIEF DESCRIPTION OF THE DRAWINGS

FIG. 1 is a block diagram illustrating a conventional flash memory device including a wordline voltage generator.

FIG. 2 is a circuit diagram illustrating a conventional regulator including a trimming circuit.

FIGS. 3 and 4 are circuit diagrams illustrating conventional trimming circuits.

FIG. 5 is a vertical cross section of the trimming circuit of FIG. 3.

FIG. 6 is a graphic diagram showing a waveform of a signal output from the regulator including the trimming circuit shown in FIGS. 3 through 5.

FIGS. 7 and 8 are circuit diagrams illustrating trimming circuits according to embodiments of the present invention.

FIG. 9 illustrates a vertical cross section of the trimming circuit shown in FIG. 7.

### DETAILED DESCRIPTION OF PREFERRED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A trimming circuit of a semiconductor memory device according to embodiments of the present invention may include a plurality of high voltage transistors isolated in respective separate well regions. Because the well regions are isolated, mutual interference between the transistors of the trimming circuit may be reduced, and a body effect causing variation of threshold voltage may be reduced so that a more a precise voltage division may be provided. Hereinafter, embodiments of the present invention will be described together with the accompanying drawings.

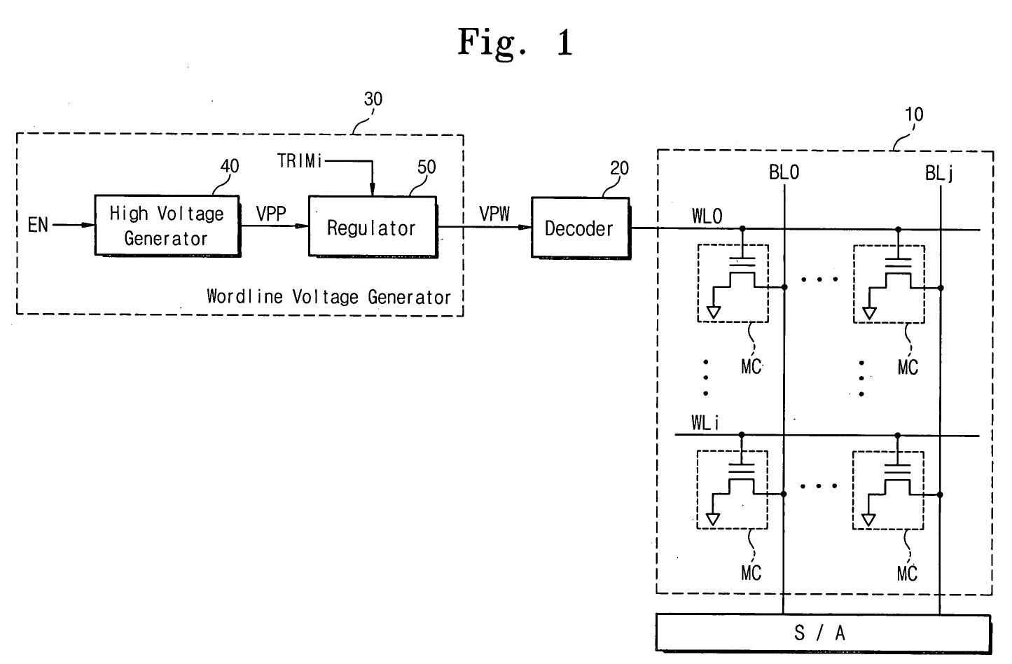

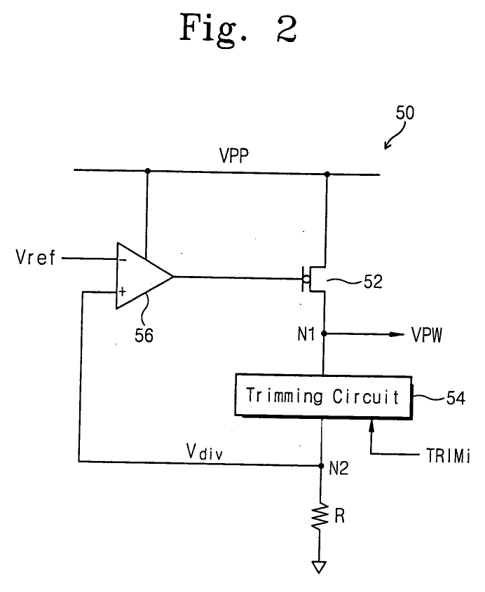

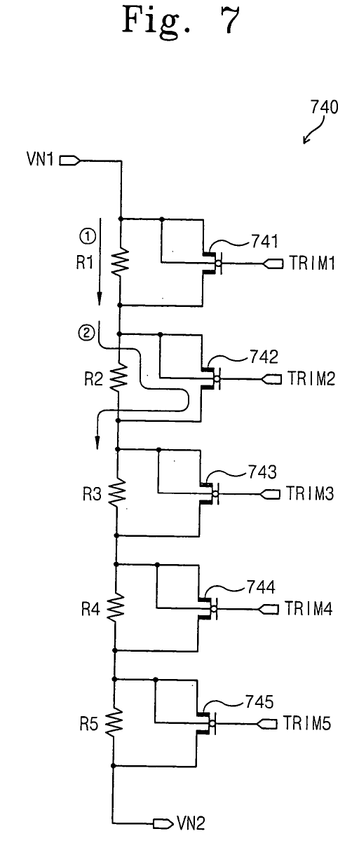

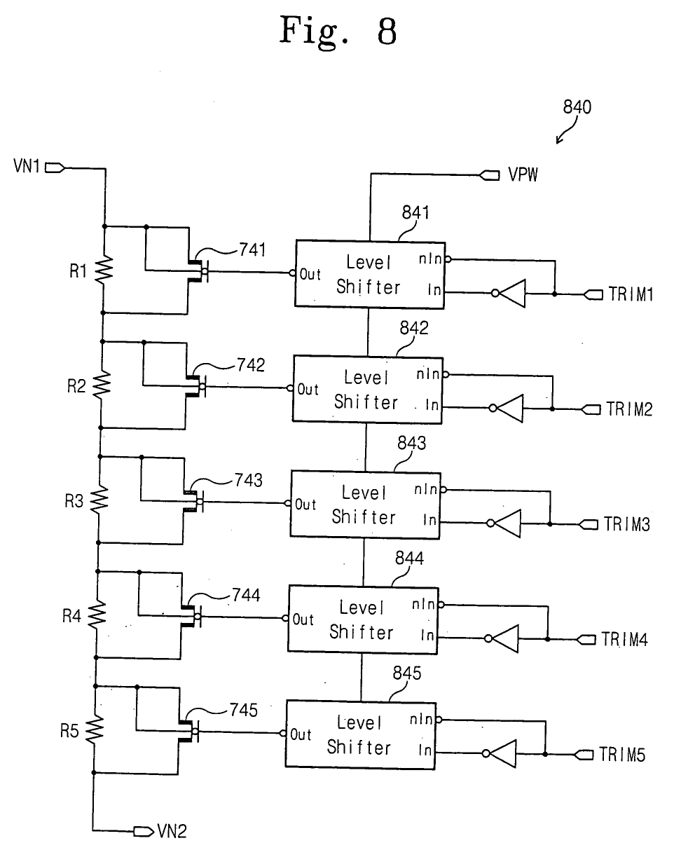

FIGS. 7 and 8 are circuit diagrams of trimming circuits according to embodiments of the present invention. FIG. 7 shows a trimming circuit 740 without level shifters, and FIG. 8 shows a trimming circuit 840 including level shifters 841-845. In the trimming circuit 840 of FIG. 8, the level shifters 841-845 transform voltage levels into voltages to be trimmed. Thus, operations of the trimming circuit 740 of FIG. 7 will be described as representative of the circuits of FIG. 7 and FIG. 8. Moreover, the trimming circuit of FIG. 7 or the trimming circuit of FIG. 8 may be used as the trimming circuit 54 in the regulator 50 of FIGS. 1 and 2 according to embodiments of the present invention. The voltage VN1 of FIGS. 7-9 may be a voltage at a first node N1 shown in FIG. 2, and the voltage VN2 of FIGS. 7-9 may be a voltage at a second node N2 shown in FIG. 2.

Referring to FIG. 7, the trimming circuit 740 may include a plurality of PMOS transistors 741-745 connected in series between the first and second nodes, N1 and N2. Resistors R1-R5 may be connected between sources and drains of respective PMOS transistors 741-745 for voltage division. The PMOS transistors 741-745 may act as switches to set current paths through the resistors R1-R5 corresponding thereto.

The PMOS transistors 741-745 may carry out switching operations in response to the trimming signals TRIMi (i is 1-5). The switching operations by the PMOS transistors 741-745 may change a current path between the first and second nodes N1 and N2. For example, if the first PMOS transistor 741 is turned off by providing a first trimming control signal TRIM1 of high level, current may flow -substantially through the first resistor RI (and not through PMOS transistor 741). And, if the second PMOS transistor 742 is turned on by providing a second trimming control signal TRIM2 of low level, the current may flow substantially through the second PMOS transistor 742 and not through the second resistor R2. As a result, the divided voltage Vdiv from the trimming circuit 740 (i.e., the voltage VN2 of the second node N2) may be changed. The trimming circuit 740 of FIG. 7 may be fabricated from NMOS transistors instead of the PMOS transistors, or from a combination of NMOS and PMOS transistors.

In the trimming circuit 740 according to embodiments of the present invention, the transistors 741-745 may each be formed in respective well regions, and the respective well regions may be isolated from each other to reduce variation of threshold voltages due to the body effect. The well regions of respective transistors 741-745 may be formed in a same substrate. A source, drain, and bulk of each transistor may be formed in/on a respective well region. The source of the PMOS transistor (or drain of the NMOS transistor) may be connected to its bulk within its corresponding well region. A high voltage of VN1 may be applied to the source and the bulk (of the first PMOS transistor 741) from the first node N1. The drain of each PMOS transistor is connected to the source of the next adjacent PMOS transistor. The drain-to-source connection between adjacent transistors enables the high voltage VN1 to be transferred from a previous transistor to a next transistor along the serial connection. Moreover, a source-to-body connection may be provided between the source of a previous transistor and a body of a next transistor.

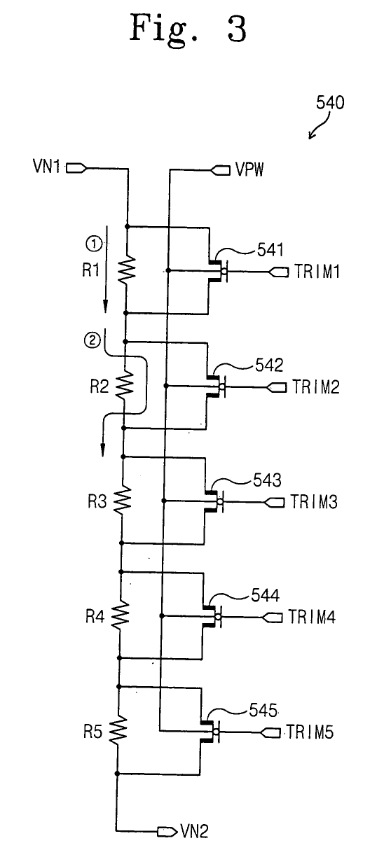

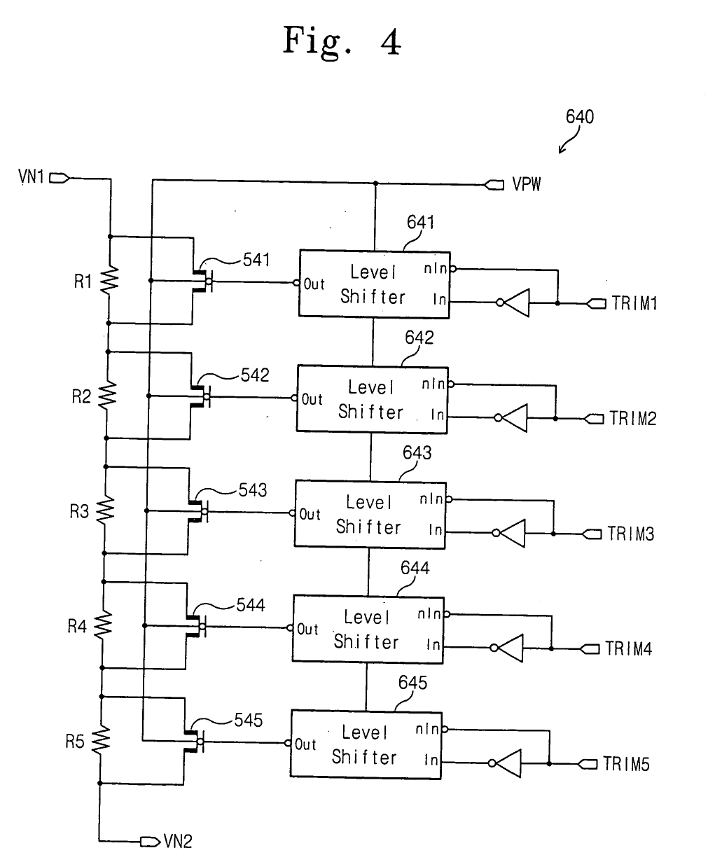

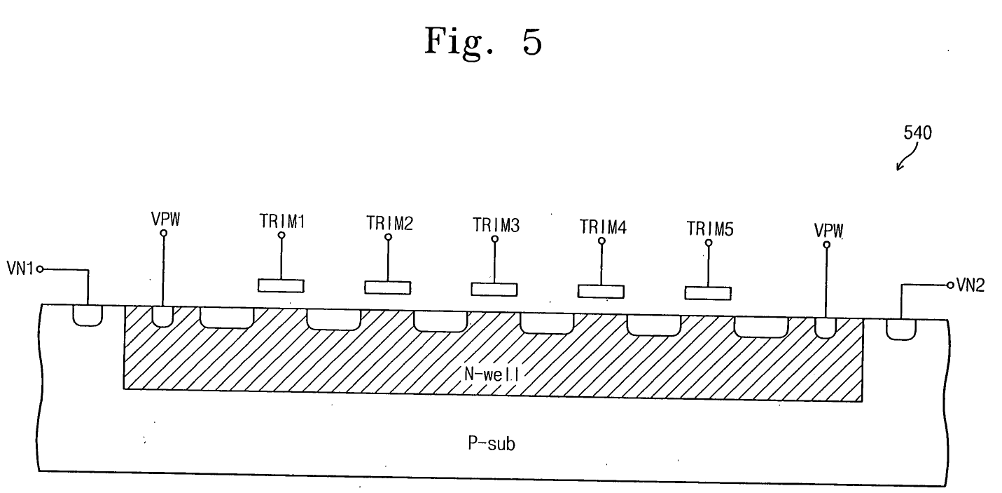

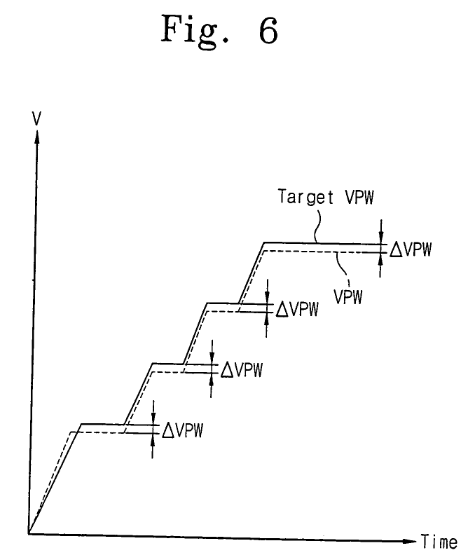

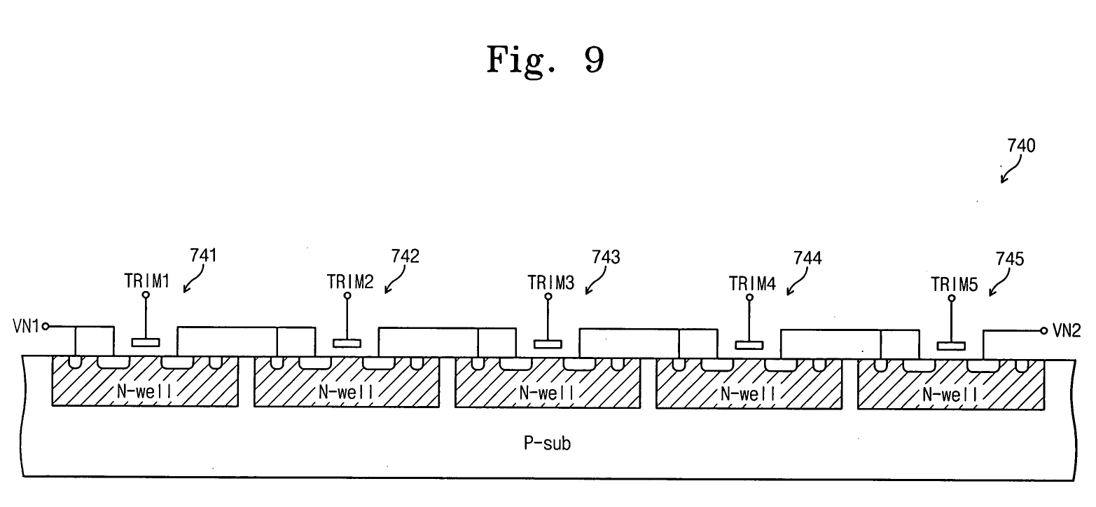

With the arrangement of the well regions shown in FIG. 9, a trimming circuit according to embodiments of the present invention may have a single path to apply the high voltage VN1, without requiring independent paths to apply the high voltages VN1 and VPW as illustrated in FIGS. 3 and 4. A same high voltage path may thus provide the same voltage at the source and bulk of a transistor so that a voltage of the source and bulk of a transistor may be substantially equal, in contrast to the examples of FIGS. 3 and 4 where a voltage difference between the source and the bulk for each transistor may vary due to the independent high voltage paths. Further, the well regions of the transistors of the trimming circuit 740 may be isolated from each other. Throughout the well regions, the sources and drains of the transistors may be sequentially connected with each other along the serial connection of the transistors, so that the body effect may be reduced in the high voltage condition where the source voltage rapidly increases. As a result, a variation of threshold voltages of the transistors may be reduced to provide a more precise voltage division.

FIG. 9 illustrates a vertical cross section of the trimming circuit shown in FIG. 7. Referring to FIG. 9, the PMOS transistors 741-745 of the trimming circuit 740 may be formed in respective isolated well regions (i.e., N-wells). Within the well region of each transistor, the corresponding source, drain, and bulk (i.e., the well region) may be formed. With PMOS transistors as shown in FIGS. 7-9, the source of each transistor may be connected to the bulk. If the transistor is an NMOS transistor, the drain and bulk may be connected to each other within the -corresponding well region. Each of the well regions of the transistors 741-745 may be connected to the drain of an adjacent transistor. The connection between a well region and a drain of an adjacent transistor may be accomplished with a metal connection. A voltage signal may be transferred from the adjacent transistor by way of the metal connection, and the transistor may be biased by the voltage provided from the drain of the adjacent transistor.

A voltage difference between a source and a bulk of each transistor of the trimming circuit 740 (or 840) may be reduced to reduce a body effect, to thereby provide more-precise voltage control.

A voltage trimming circuit of a semiconductor memory device (e.g., flash memory) according to embodiments of the present invention may provide control of a voltage used in programming the memory device with improved precision.

While the present invention has been particularly shown and described with reference to embodiments thereof, it will be understood by those skilled in the art that various changes in form and details may be made therein without departing from the spirit and scope of the invention as defined by the appended claims and their equivalents.

What is claimed is:

1. A trimming circuit comprising:
a plurality of resistors coupled in series between an output node and a reference voltage;
a plurality of-transistors wherein each transistor is electrically coupled in parallel with a respective one of the resistors, wherein each of the transistors includes a respective well region and wherein well regions of different transistors are isolated.

2. A trimming circuit according to claim 1 wherein the well regions of the different transistors comprise separate doped regions of a same substrate.

3. A trimming circuit according to claim 1 wherein the plurality of transistors comprise a plurality-of field effect transistors.

4. A trimming circuit according to claim 3 wherein a well region of a first one of the plurality of transistors is coupled to a source/drain of a second one of the plurality of transistors.

5. A trimming circuit according to claim 1 wherein each of the transistors includes source and drain regions in the respective well region.

6. A trimming circuit according to claim 5 wherein one of the transistors is a P-type field effect transistor, and wherein the source region of the P-type transistor is electrically coupled to the well region of the P-type transistor.

7. A trimming circuit according to claim 6 wherein the source and well regions of the P-type transistor are electrically coupled via a metal line providing a direct electrical coupling therebetween.

8. A trimming circuit according to claim 5 wherein one of the transistors is an N-type field effect transistor, and wherein the drain region of the N-type transistor is electrically coupled to the well region of the N-type transistor.

9. A trimming circuit according to claim 8 wherein the drain and well regions of the N-type transistor are electrically coupled via a metal line providing a direct electrical coupling therebetween.

10. A trimming circuit according to claim 1 further comprising:
a memory cell array including a plurality of memory cells; and
a decoder configured to couple the output node with at least one of the memory cells responsive to a memory cell address.

11. A trimming circuit according to claim 10 wherein the memory cells comprise flash memory cells.

12. An integrated circuit memory device comprising:
a memory cell array including a plurality of memory cells;
a voltage generator configured to generate a programming voltage for the memory cell array; and
a trimming circuit coupled to an output of the voltage generator wherein the trimming circuit includes a plurality of resistors coupled in series between an output node of the voltage generator and a reference voltage, and a plurality of transistors wherein each transistor is electrically coupled in parallel with a respective one of the resistors, wherein each of the transistors includes a respective well region and wherein well regions of different transistors are isolated.

13. An integrated circuit memory device according to claim 12 wherein the well regions of the different transistors comprise separate doped regions of a same substrate.

14. An integrated circuit memory device according to claim 12 wherein the plurality of transistors comprise a plurality of field effect transistors.

15. An integrated circuit memory device according to claim 14 wherein a well region of a first one of the plurality of transistors is coupled to a source/drain of a second one of the plurality of transistors.

16. An integrated circuit memory device according to claim 12 wherein each of the transistors includes source and drain regions in the respective well region.

17. An integrated circuit memory device according to claim 16 wherein one of the transistors is a P-type field effect transistor, and wherein the source region of the P-type transistor is electrically coupled to the well region of the P-type transistor.

18. An integrated circuit memory device according to claim 17 wherein the source and well regions of the P-type transistor are electrically coupled via a metal line providing a direct electrical coupling therebetween.

19. An integrated circuit memory device according to claim 16 wherein one of the transistors is an N-type field effect transistor, and wherein the drain region of the N-type transistor is electrically coupled to the well region of the N-type transistor.

20. An integrated circuit memory device according to claim 19 wherein the drain and well regions of the N-type transistor are electrically coupled via a metal line providing a direct electrical coupling therebetween.

21. An integrated circuit memory device according to claim 12, further comprising:
a decoder configured to couple the output node of the voltage generator with at least one of the memory cells responsive to a memory cell address.

22. An integrated circuit memory device according to claim 12 wherein the memory cells comprise flash memory cells.
